(19) United States
(12) Patent Application Publication
(10) Pub. No.: US 2024/0059087 A1
(43) Pub. Date: Feb. 22, 2024

(54) GRAVURE PRINTING DEVICE

(71) Applicant: KOMORI CORPORATION, Tokyo (JP)

(72) Inventors: Shunichi HARAGUCHI, Ibaraki (JP); Chisato OYAMA, Ibaraki (JP); Ikuo SUGIMOTO, Ibaraki (JP)

(21) Appl. No.: 17/754,579

(22) PCT Filed: Oct. 8, 2020
(86) PCT No.: PCT/JP2020/038151

§ 371 Date: Apr. 6, 2022

(30) Foreign Application Priority Data
Oct. 8, 2019 (JP) 2019-185265

(51) Int. Cl. B41M 1/10; B41F 33/00; B41F 9/06

(52) U.S. Cl. CPC B41M 1/10; B41F 33/00; B41F 9/06

(57) ABSTRACT

A gravure printing device includes a substrate stage (11) on which a substrate (2) is fixed, an intaglio plate (21) for holding conductive paste, and a control device (7) for controlling a series of printing operations including a supply operation of supplying conductive paste (3) to a printing pattern of the intaglio plate (21) and a transfer operation of transferring the conductive paste (3) to the substrate (2). The control device (7) repeatedly performs the series of printing operations a plurality of times with respect to the identical printing position on the substrate (2). A printing pattern laminate made of the conductive paste laminated into the shape of the printing pattern is formed on the substrate (2). This makes it possible to form lines and bumps on a substrate made of a heat-sensitive material, while preventing the occurrence of metamorphosis of the substrate made of the heat-sensitive material.

### TECHNICAL FIELD

The present invention relates to a gravure printing device for forming lines and bumps of a flexible substrate.

### BACKGROUND ART

In the field of printed electronics (PE), a gravure offset printing device is sometimes used as described in patent literature 1. The gravure offset printing device is used to accurately print fine lines on a printed substrate (to be simply referred to as a substrate hereinafter).

A projecting electrode called a bump is known as a connecting electrode to be formed on a substrate. Conventional bumps are often formed by using solder.

A solder bump is formed as follows. First, solder paste is printed on an electrode of a substrate by a screen printing method, or a solder ball is placed on an electrode of a substrate. Then, the substrate is inserted into a reflow oven, and the solder paste or the solder ball is melted by performing a reflow process. After that, the solder paste or the solder ball is solidified by cooling. When performing the reflow process on the solder paste or the solder ball, the temperature is generally about 240° C. to 260° C.

As substrates to be used in the field of printed electronics, substrates formed by using heat-sensitive materials such as PET (polyethylene terephthalate) and PEN (polyethylene naphthalate) are known.

### RELATED ART LITERATURE

### Patent Literature

Patent Literature 1: Japanese Patent Laid-Open No. 2014-73653

### DISCLOSURE OF INVENTION

### Problem to be Solved by the Invention

The heat resistant temperature of a heat-sensitive material is lower than the temperature of the reflow process. Therefore, when solder paste or a solder ball is used to form a bump on a substrate made of the heat-sensitive material, metamorphosis (distortion) of the substrate may occur, and this may degrade the quality.

It is an object of the present invention to form lines and bumps on a substrate made of a heat-sensitive material while preventing the occurrence of metamorphosis of the substrate made of the heat-sensitive material.

### Means of Solution to the Problem

To achieve this object, a gravure printing device according to the present invention includes a substrate stage configured to hold a substrate as an object of printing, a plate configured to hold conductive paste in a predetermined printing pattern, and a control device configured to control a series of printing operations including a supply operation of supplying the conductive paste to the printing pattern of the plate and a transfer operation of transferring the conductive paste to the substrate, wherein the control device is configured to repeatedly perform the series of printing operations a plurality of times with respect to an identical printing position on the substrate, and a printing pattern laminate made of the conductive paste laminated into a shape of the printing pattern is formed on the substrate.

A gravure printing device according to the present invention includes a substrate stage configured to hold a substrate as an object of printing, a plate including a plurality of identical printing pattern portions configured to hold conductive paste in a predetermined printing pattern, and a control device configured to control a series of printing operations including a supply operation of supplying the conductive paste to all the printing pattern portions of the plate and a transfer operation of transferring the conductive paste to the substrate, wherein the control device is configured to cause the conductive paste for each printing pattern portion to be transferred to an identical printing position on the substrate, and a printing pattern laminate made of the conductive paste laminated into a shape of the printing pattern is formed on the substrate.

A gravure printing device according to the present invention includes a substrate stage configured to hold a substrate as an object of printing, a plate configured to hold conductive paste in a predetermined printing pattern, a transfer member configured to receive the conductive paste from the plate and transfer the conductive paste to the substrate, and a control device configured to control a series of printing operations from a receiving operation in which the transfer member receives the conductive paste to a transfer operation of transferring the conductive paste to the substrate, wherein the receiving operation is an operation in which the transfer member repeatedly receives the conductive paste a plurality of times from the plate to an identical receiving position, the transfer operation is an operation in which the transfer member transfers the conductive paste laminated in the identical receiving position on the transfer member to the substrate, and a printing pattern laminate made of the conductive paste laminated into a shape of the printing pattern is formed on the substrate.

### Effect of the Invention

In the present invention, a printing pattern laminate for forming lines and bumps can be formed on a substrate. When forming lines and bumps on the substrate from this printing pattern laminate, the substrate is not heated to temperatures at which metamorphosis occurs. According to the present invention, therefore, it is possible to form lines and bumps on a substrate made of a heat-sensitive material while preventing the occurrence of metamorphosis of the substrate made of the heat-sensitive material.

### BRIEF DESCRIPTION OF DRAWINGS

FIG. 1 is a block diagram showing the configuration of a gravure offset printing device according to the first embodiment;

FIG. 2A is a sectional view for explaining a printing operation;

FIG. 2B is a sectional view for explaining the printing operation;

FIG. 2C is a sectional view for explaining the printing operation;

FIG. 3 is a flowchart for explaining the operation of a control device according to the first embodiment;

FIG. 4 is a schematic view showing the lamination state of conductive paste;

FIG. 5 is a schematic view showing the lamination state of the conductive paste;

FIG. 6 is a block diagram showing the configuration of a gravure offset printing device according to the second embodiment;

FIG. 7 is a flowchart for explaining the operation of a control device according to the second embodiment;

FIG. 8 is a schematic view showing the lamination state of conductive paste;

FIG. 9 is a flowchart for explaining the operation of a control device according to the third embodiment;

FIG. 10 is a schematic view showing the lamination state of conductive paste;

FIG. 11 is a block diagram showing the configuration of a gravure offset printing device according to the fourth embodiment;

FIG. 12 is a sectional view for explaining a printing operation;

FIG. 13 is a sectional view for explaining the printing operation;

FIG. 14 is a sectional view for explaining the printing operation;

FIG. 15 is a sectional view for explaining the printing operation;

FIG. 16 is a block diagram showing the configuration of a gravure offset printing device according to the fifth embodiment;

FIG. 17A is a sectional view for explaining a printing operation;

FIG. 17B is a sectional view for explaining the printing operation;

FIG. 17C is a sectional view for explaining the printing operation;

FIG. 18A is a sectional view for explaining the printing operation;

FIG. 18B is a sectional view for explaining the printing operation; and

FIG. 18C is a sectional view for explaining the printing operation.

### BEST MODE FOR CARRYING OUT THE INVENTION

### First Embodiment

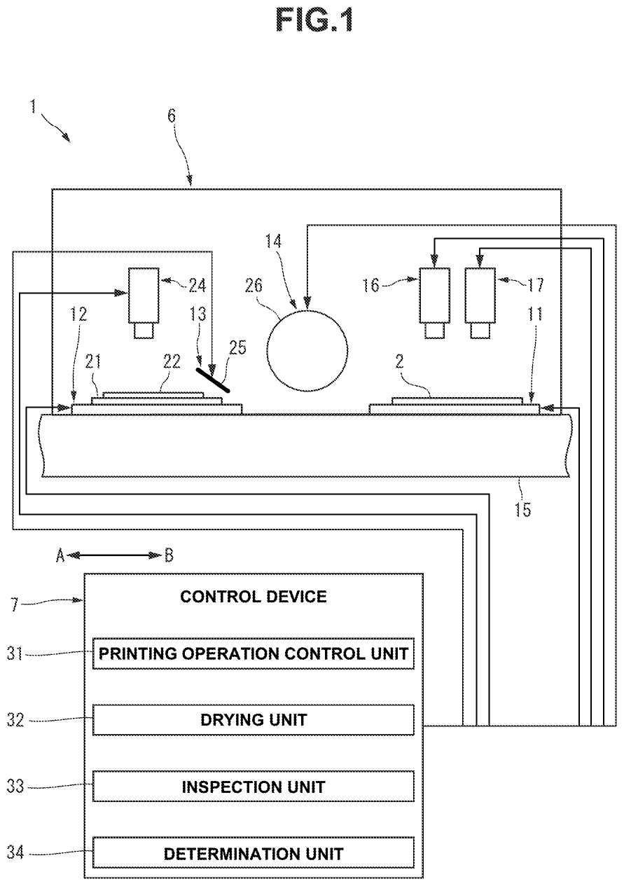

An embodiment of a gravure printing device according to the present invention will be explained in detail below with reference to FIGS. 1 to 5. In the first embodiment, an example of a case in which the invention described in claim 1 is applied to a gravure offset printing device will be explained.

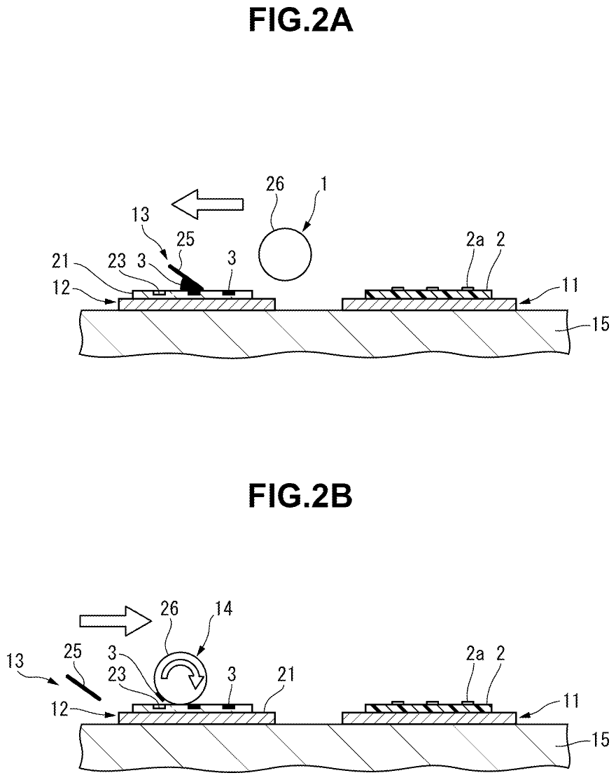

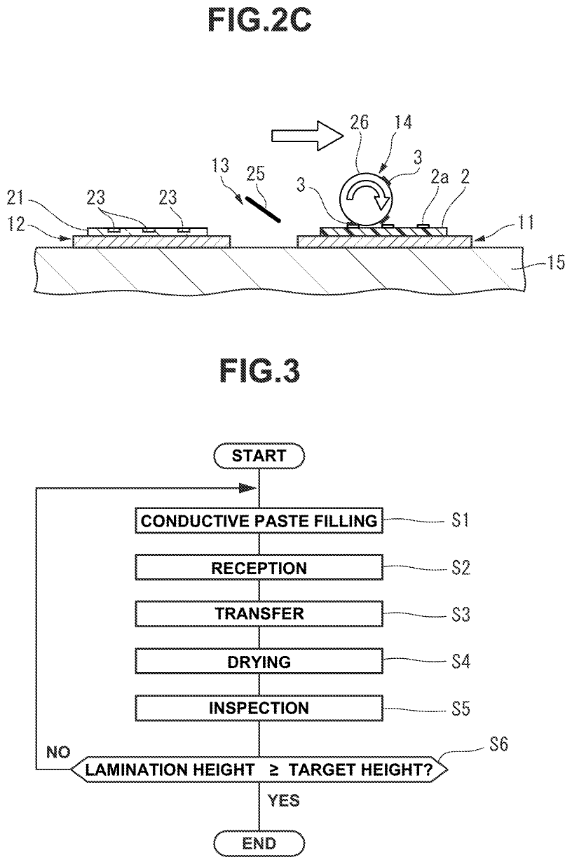

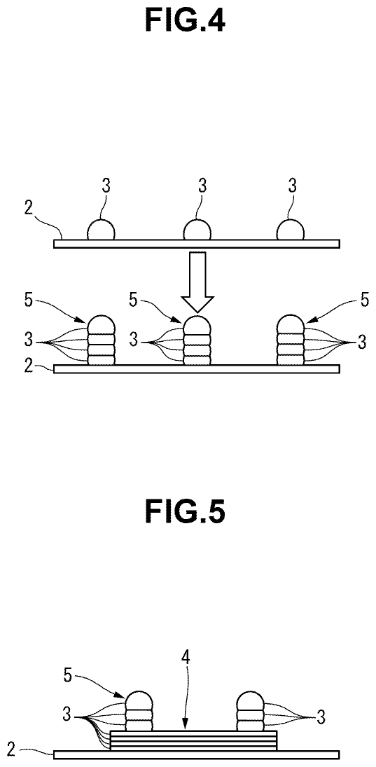

A gravure offset printing device 1 shown in FIG. 1 prints conductive paste 3 (see FIGS. 2A to 2C) on a substrate 2 as an object of printing such that multiple layers of the conductive paste 3 are laminated, and forms a line 4 (see FIG. 5) and bumps 5 (see FIG. 4) by the conductive paste 3. The substrate 2 is a flexible substrate formed by a heat-sensitive material, and has electrodes 2a (see FIGS. 2A to 2C) on which the bumps 5 are formed. As the heat-sensitive material, it is possible to use, e.g., PET (polyethylene terephthalate) or PEN (polyethylene naphthalate). As the conductive paste 3, a material that contains metal grains of, e.g., silver, gold, or body and solidifies by drying is used. In the following explanation of the configuration of the gravure offset printing device 1, it is assumed for the sake of convenience that the left direction in FIG. 1 is direction A and the right direction in FIG. 1 is direction B.

The gravure offset printing device 1 according to this embodiment includes a printing unit 6 depicted in the upper portion of FIG. 1, and a control device 7 depicted in the lower portion of FIG. 1. The printing unit 6 shown in FIG. 1 is drawn in a state in which it is viewed sideways. The printing unit 6 according to this embodiment includes a substrate stage 11 positioned on the right side in FIG. 1, a plate stage 12 positioned on the left side of FIG. 1, and a scraper 13 and a transfer member 14 positioned between the two stages 11 and 12. The substrate stage 11, the plate stage 12, the scraper 13, and the transfer member 14 are mounted on a base 15. The control device 7 (to be described later) controls the operations of these members.

The substrate 2 is horizontally fixed on the substrate stage 11. The substrate stage 11 has a function of positioning the substrate 2 in a predetermined position, and a function of holding the substrate 2 by vacuum suction or the like. A drying device 16 and an inspection device 17 are arranged near the substrate stage 11.

The drying device 16 dries the conductive paste 3. A device suitable for the type of the conductive paste 3 is used as the drying device 16. As the drying device 16, it is possible to use, e.g., a device that blows air by ventilation against the conductive paste 3 printed on the substrate 2, a device that blows warm air against the conductive paste 3, or a device that irradiates the conductive paste 3 with infrared rays. The control device 7 (to be described later) controls the operation of the drying device 16. Drying by ventilation, warm air, or infrared radiation to be performed by the drying device 16 is an auxiliary means for temporarily drying the conductive paste 3. If this temporary drying is not performed, reverse transfer to a blanket or collapse by the printing pressure (to be described later) occurs because the viscosity of the conductive paste 3 is too low. The conductive paste 3 is hardened to some extent by being temporarily dried on the machine. The conductive paste 3 transferred to the substrate 2 is put into an oven or a heating furnace (neither is shown) and finally calcined.

When using the conductive paste 3, conduction is obtained not by melting the metal grains dispersed in the paste, but by decomposing the resin component of the paste in which the metal grains are dispersed, thereby bringing the metal grains into contact with each other. Since the final calcination need only decompose the resin component, it can be performed at a relatively low temperature compared to the temperature when forming bumps by using solder paste or solder balls (i.e., when melting solder).

The inspection device 17 digitalizes the surface shape of the conductive paste 3 printed on the substrate 2, and transmits this shape data to the control device 7. A laser scanner or the like can be used as the inspection device 17. The control device 7 (to be described later) controls the operation of the inspection device 17.

An intaglio plate 21 as a “plate” in the present invention is horizontally fixed on the plate stage 12. The plate stage 12 has a function of positioning the intaglio plate 21 in a predetermined position, and a function of holding the intaglio plate 21. As shown in FIGS. 2A to 2C, the intaglio plate 21 according to this embodiment is a flat plate formed into a flat shape. A printing pattern portion 22 (see FIG. 1) for holding the conductive paste 3 so as to form a predetermined printing pattern is formed on the upper surface of the intaglio plate 21. Recessed portions 23 (see FIGS. 2A to 2C) to be filled with the conductive paste 3 are formed in the printing pattern portion 22. A paste supply device 24 (see FIG. 1) for supplying the conductive paste 3 to the intaglio plate 21 is installed above the plate stage 12. The control device 7 (to be described later) controls the operation of the paste supply device 24.

The scraper 13 scrapes excess conductive paste 3 from the upper surface of the intaglio plate 21, and includes a blade 25 formed by a band-like plate. The scraper 13 is so configured as to move in a direction (the left-and-right direction, i.e., the A-B direction in FIG. 1) in which the substrate stage 11 and the plate stage 12 are aligned, together with the transfer member 14 to be described below.

The transfer member 14 is a roll around the circumferential surface on which a blanket 26 is wound. The transfer member 14 according to this embodiment has a function of rotating, a function of moving in the A-B direction between the substrate stage 11 and the plate stage 12, and a function of moving vertically.

The control device 7 includes a printing operation control unit 31, a drying unit 32, an inspection unit 33, and a determination unit 34, and controls the operations of the individual devices of the printing unit 6 so as to implement a predetermined printing method. The printing operation control unit 31 controls the operations of the substrate stage 11, the plate stage 12, the scraper 13, the transfer member 14, the paste supply device 24, and the like. The drying unit 32 controls the operation of the drying device 16. The inspection unit 33 inspects the surface shape and the presence/absence of inclination of the bump 5 based on the shape data transmitted from the inspection device 17, and measures the lamination height of the bump 5. The determination unit 34 compares the lamination height of the bump 5 with a predetermined target height, and determines whether to perform printing again or terminate printing.

Next, the operation of the gravure offset printing device 1 according to this embodiment will be explained below, together with the explanation of a printing method, with reference to a flowchart shown in FIG. 3. First, a printing method of forming the bump 5 on the substrate 2 will be explained. When performing printing by using the gravure offset printing device 1, the substrate 2 is positioned and fixed on the substrate stage 11 in advance. When a printing operation is started, the conductive paste 3 is filled in the recessed portions 23 of the intaglio plate 21, i.e., conductive paste filling step S1 is performed.

In conductive paste filling step S1, the paste supply device 24 drops a predetermined amount of the conductive paste 3 on the intaglio plate 21. Then, as shown in FIG. 2A, the scraper 13 and the transfer member 14 are moved in a direction in which they are separated from the substrate stage 11 in a state in which the lower end of the blade 25 of the scraper 13 is in contact with the intaglio plate 21. During this operation, the transfer member 14 is moved to a position higher than the intaglio plate 21. The conductive paste 3 is filled in the recessed portions 23 when the blade 25 passes over the intaglio plate 21.

Reception step S2 is performed after the scraper 13 moves. In reception step S2, the blade 25 of the scraper 13 is separated from the intaglio plate 21, and the transfer member 14 performs a receiving operation. The receiving operation is an operation in which the transfer member 14 and the scraper 13 are moved toward the substrate stage 11 while the transfer member 14 is moved down and pushed against the intaglio plate 21. In this operation, the transfer member 14 rotates as it moves in contact with the intaglio plate 21, and the conductive paste 3 in the recessed portions 23 is received by the transfer member 14 along with this rotation as shown in FIG. 2B.

In this specification, the movement of the conductive paste 3 from the intaglio plate 21 to the transfer member 14 is called “reception”. Also, in this specification, the movement of the conductive paste 3 from the transfer member 14 to the substrate 2 or to the conductive paste 3 on the substrate 2 is called “transfer”. When the transfer member 14 rolls to one end on the intaglio plate 21, the conductive paste 3 is received by the blanket 26 so as to form a predetermined printing pattern.

The transfer member 14 performs a moving operation after the transfer member 14 receives the conductive paste 3 as described above. The moving operation is an operation in which the transfer member 14 moves from the plate stage 12 to the substrate stage 11. Transfer step S3 is performed after the transfer member 14 moves to the substrate stage 11.

As shown in FIG. 2C, transfer step S3 performs a transfer operation in which the transfer member 14 moves and rolls on the substrate 2 and transfers the conductive paste 3 to the substrate 2. Since the transfer member 14 rolls and moves on the substrate 2 in a state in which the transfer member 14 is pushed against the substrate 2, the conductive paste 3 on the transfer member 14 is transferred from the blanket 26 to the electrodes 2a on the substrate 2. After the conductive paste 3 is transferred to the substrate 2, the transfer member 14 moves up from the substrate 2 and moves toward the plate stage 12.

Then, drying step S4 is performed. In drying step S4, the drying device 16 blows warm air against the conductive paste 3 on the substrate 2. Drying step S4 is performed for a time period during which the solvent component evaporates from the conductive paste 3 and the hardness of the conductive paste 3 becomes a predetermined value. This predetermined value is a value at which the conductive paste 3 has hardness with which the shape remains unchanged even when another layer of the conductive paste 3 is overlaid on the conductive paste 3. That is, the drying device 16 drives the conductive paste 3 transferred as a lower layer to the substrate 2 before the conductive paste 3 functioning as an upper layer is printed on the conductive paste 3 functioning as the lower layer. When drying step S4 is performed, another layer of the conductive paste 3 can be transferred onto the conductive paste 3.

Inspection step S5 is performed after drying step S4 is performed. In inspection step S5, the inspection unit 33 of the control device 7 inspects the shape of the conductive paste 3 on the substrate 2 by using the inspection device 17, and measures the lamination height of the conductive paste 3. When the lamination height is measured, next determination step S6 is performed.

Determination step S6 determines whether the lamination height of the conductive paste 3 has reached a predetermined target height. In addition, although not shown, determination step S6 also determines whether the shape of the conductive paste 3 detected in inspection step S5 is normal. If the shape of the conductive paste 3 is abnormal, a printing operation of correcting the shape is performed, or a printing operation stops and is canceled. When abnormality is detected, it is also possible to notify the worker of the abnormality by using an alarm lamp (not shown) installed in the printing device.

If the lamination height of the conductive paste 3 has not reached the predetermined target height, the conductive paste 3 is printed on the substrate 2 again. That is, the process returns to conductive paste filling step S1 and repeats the above-described printing operations. Consequently, the series of printing operations including the receiving operation, the moving operation, and the transfer operation by the transfer member 14 are repetitively performed a plurality of times in the identical printing position on the substrate 2. The transfer operation in which the transfer member 14 transfers a next layer of the conductive paste 3 onto the conductive paste 3 on the substrate 2 is performed in a state in which the transfer member 14 has risen from the preceding position by a height equal to the thickness of the conductive paste 3. During the operation, the height (the printing pressure) of the transfer member 14 is controlled in accordance with the thickness of the laminated conductive paste 3, the inclination of the laminate (the bump 5) of the conductive paste 3, or the like. For example, if the laminate of the conductive paste 3 inclines, the transfer operation is performed by placing the transfer member 14 in a position higher than a normal position so as to decrease the printing pressure. In this embodiment, the operation of controlling the pressing pressure as described above is equivalent to a “correcting operation” in the invention described in claim 8.

The gravure offset printing device 1 according to this embodiment has a high repeat accuracy. Therefore, no intermediate positioning is performed although the printing operation is repeated a plurality of times. That is, when performing the printing operation again from conductive paste filling step S1, the substrate 2 and the intaglio plate 21 need not be positioned with respect to the transfer member 14.

Since the printing operation including steps from conductive paste filling step S1 to determination step S6 is repeated a plurality of times, a laminate of the conductive paste 3 is formed by transferring and overlaying another layer of the conductive paste 3 by the next printing operation, on the conductive paste 3 transferred and dried on the substrate 2, as shown in FIG. 4. The printing operation is terminated when the lamination height has reached the predetermined target height in inspection step S5.

When the lamination height of the conductive paste 3 has reached the target height, a printing pattern laminate including the conductive paste 3 laminated into the shape of the printing pattern on the substrate 2 is formed. In this embodiment, the printing pattern laminate forms the bump 5.

In the above-described embodiment, an example in which the bumps 5 are formed on the substrate 2 is disclosed. As shown in FIG. 5, however, it is also possible to first perform lamination printing of the lines 4 and then laminate the bumps 5 by using another plate.

In the gravure offset printing device 1 configured as described above, the conductive paste 3 laminated by applying the gravure offset printing method forms the lines 4 and the bumps 5 of the substrate 2. When forming the lines 4 and the bumps 5 on the substrate 2 by using the laminated conductive paste 3, the substrate 2 is not heated to temperatures at which metamorphosis occurs. According to this embodiment, therefore, it is possible to form the lines 4 and the bumps 5 on the substrate 2 made of a heat-sensitive material, while preventing the occurrence of metamorphosis of the substrate 2 made of the heat-sensitive material.

### Second Embodiment

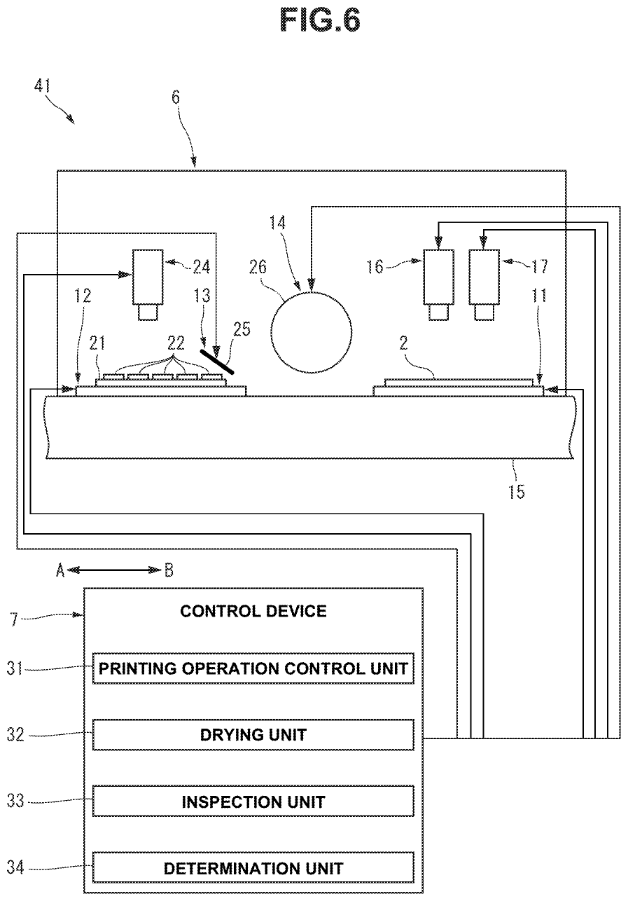

The second embodiment of the gravure printing apparatus according to the present invention will be explained in detail below with reference to FIGS. 6 to 8. In the second embodiment, an example in which the invention described in claim 2 is applied to a gravure offset printing device will be explained. The same reference numerals as explained with reference to FIGS. 1 to 5 denote the same or equivalent members in FIGS. 6 to 8, and a detailed explanation thereof will appropriately be omitted.

A gravure offset printing device 41 shown in FIG. 6 has the same configuration as that of the gravure offset printing device 1 according to the first embodiment, except the configurations (the printing method) of an intaglio plate 21 and a control device 7.

The intaglio plate 21 according to this embodiment includes a plurality of printing pattern portions 22. The printing pattern portions 22 hold conductive paste 3 so as to form identical printing patterns, and are arranged in the A-B direction along which a transfer member 14 moves.

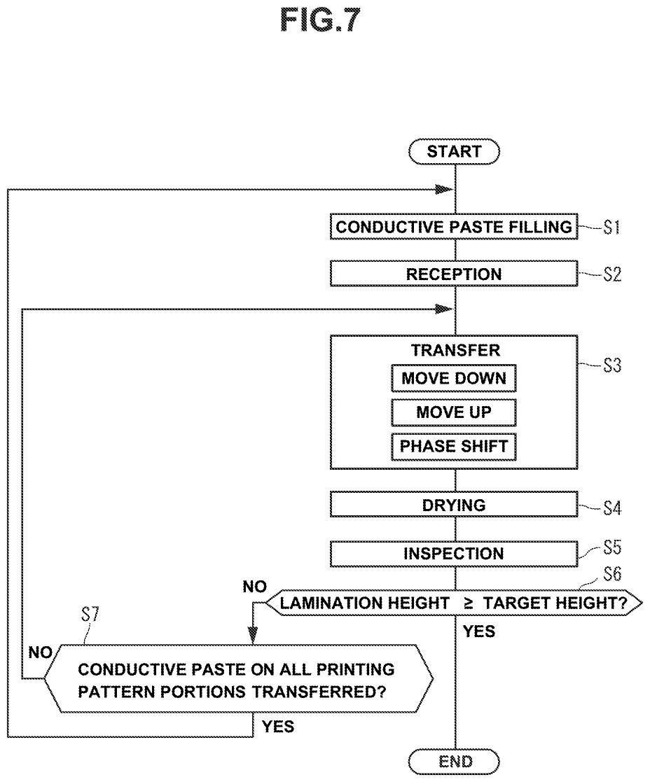

The control device 7 of the gravure offset printing device 41 according to this embodiment is so configured as to perform transfer a plurality of times when the transfer member 14 performs reception once. A printing method to be performed by the control device 7 will be explained in detail below with reference to a flowchart shown in FIG. 7. When the control device 7 according to this embodiment starts controlling a printing operation, the conductive paste 3 is filled in recessed portions 23 of all the printing pattern portions 22 of the intaglio plate 21 in conductive paste filling step S1. Then, reception step S2 is performed.

In reception step S2, a receiving operation is performed such that the transfer member 14 rotates in contact with the intaglio plate 21 and receives the conductive paste 3 from the plurality of printing pattern portions 22 of the intaglio plate 21 while changing receiving positions. When this receiving operation is performed, printing patterns formed by the conductive paste 3 on the individual printing pattern portions 22 are arranged at predetermined intervals in the circumferential direction of the transfer member 14.

After that, the transfer member 14 moves to a substrate stage 11 and performs a transfer operation in transfer step S3. In transfer step S3 of this embodiment, the control device 7 causes the conductive paste 3 on the individual printing pattern portions 22 to be transferred to identical printing positions on a substrate 2. More specifically, the transfer member 14 moves down and transfers the conductive paste 3 to the substrate 2, and then moves up and rotates so that the phase shifts at a predetermined angle. This predetermined angle is an angle at which the conductive paste 3 on the next printing pattern portion 22 moves to the lowermost position of the transfer member 14.

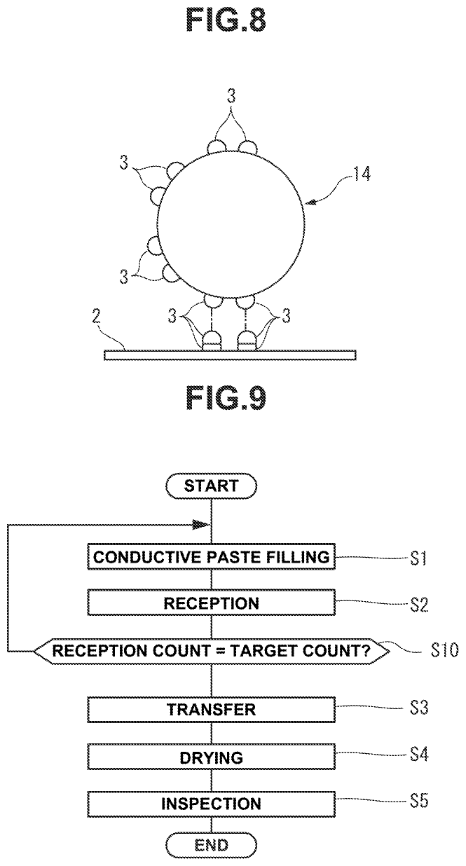

After the conductive paste 3 on one printing pattern portion 22 is transferred to the substrate 2, drying step S4, inspection step S5, and determination step S6 are performed in this order. If the lamination height of the conductive paste 3 laminated on the substrate 2 has not reached a target height, determination step S7 is performed. In the determination step S7, whether the conductive paste 3 on all the printing pattern portions 22 received on the transfer member 14 is transferred to the substrate 2 is determined. A determination unit 34 of the control device 7 performs this determination. If the conductive paste 3 remains on the transfer member 14, the process returns to transfer step S3, and the conductive paste 3 is transferred again to the identical printing positions on the substrate 2. The transfer operation is thus performed such that the transfer member 14 repeatedly transfers the conductive paste 3 on the individual printing pattern portions 22 to the identical printing positions on the substrate 2 a plurality of times. Consequently, as shown in FIG. 8, the conductive paste 3 is laminated on the identical printing positions on the substrate 2.

If it is determined in determination step S7 that the conductive paste 3 on the transfer member 14 is entirely transferred to the substrate 2, the process returns to conductive paste filling step S1, and the above-described operation is repeated. Then, the printing operation is terminated when the lamination height of the conductive paste 3 laminated on the substrate 2 has reached the target height, thereby forming a printing pattern laminate (a bump 5) made of the conductive paste 3 laminated into the printing pattern shape on the substrate 2.

Accordingly, this embodiment can also form lines 4 and bumps 5 on the substrate 2 made of a heat-sensitive material while preventing the occurrence of metamorphosis of the substrate 2 made of the heat-sensitive material, in the same manner as in the first embodiment.

### Third Embodiment

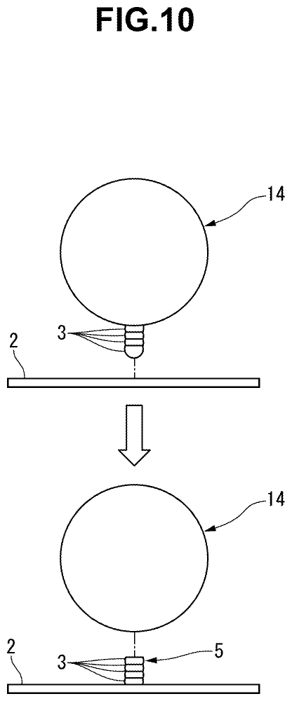

The printing methods performed by the gravure offset printing devices 1 and 41 according to the first and second embodiments can also be a printing method as shown in FIGS. 9 and 10. The same reference numerals as explained with reference to FIGS. 1 to 8 denote the same or equivalent members in FIGS. 9 and 10, and a detailed explanation thereof will properly be omitted. A gravure offset printing device for performing the printing method of this embodiment is equivalent to the gravure printing device described in claim 5 of the present invention. The gravure offset printing device according to the third embodiment is not shown in any drawing because only a printing operation (the printing method) differs from those of the gravure offset printing devices 1 and 41 disclosed in the first and second embodiments.

The printing method according to this embodiment is so configured that reception by a transfer member 14 is performed a plurality of times as shown in a flowchart of FIG. 9, and a bump 5 is formed by one transfer as shown in FIG. 10. According to this printing method, conductive paste 3 is filled in recessed portions 23 of an intaglio plate 21 in conductive paste filling step S1, and then reception step S2 is performed.

In reception step S2, the transfer member 14 rotates in contact with the intaglio plate 21 and receives the conductive paste 3. Subsequently, determination step S10 is performed. Determination step S10 determines whether the count at which the transfer member 14 received the conductive paste 3 has reached a predetermined target count. A determination unit 34 of a control device 7 performs this determination. If the reception count is smaller than the target count, the process returns to conductive paste filling step S1, and the transfer member 14 receives the conductive paste 3 from the intaglio plate 21 again.

Accordingly, the transfer member 14 according to this embodiment performs a receiving operation in which the transfer member 14 receives the conductive paste 3 from the intaglio plate 21 to the identical receiving position a plurality of times. After the reception count reaches the target count, a transfer operation in which the transfer member 14 transfers the conductive paste 3 to a substrate 2 is performed in transfer step S3. In transfer step S3 according to this embodiment, as shown in FIG. 10, multiple layers of the conductive paste 3 received by and overlaid on the transfer member 14 a plurality of times are transferred to the substrate 2 at once.

After transfer step S3 is performed, the conductive paste 3 is dried in drying step S4. Since drying step S4 is thus performed, a printing pattern laminate (the bump 5) made of the conductive paste 3 laminated into the shape of the printing pattern is formed on the substrate 2. Then, inspection step S5 is performed to inspect the bump 5 made of the conductive paste 3 laminated on the substrate 2.

Accordingly, this embodiment can also form lines 4 and bumps 5 on the substrate 2 made of a heat-sensitive material while preventing the occurrence of metamorphosis of the substrate 2 made of the heat-sensitive material, in the same manner as in the first embodiment.

In each of the above-described embodiments, an example in which the intaglio plate 21 is formed by using a flat plate is disclosed. However, the present invention is not limited to this. The intaglio plate 21 to be used in the gravure offset printing devices 1 and 41 can also be a cylindrical sleeve plate.

In addition, in each of the above-described embodiments, an example in which the positions of the substrate stage 11 and the plate stage 12 remain unchanged and the scraper 13 and the transfer member 14 move with respect to the substrate stage 11 and the plate stage 12 is disclosed. However, the gravure printing device according to the present invention is not limited to this printing method. That is, although not shown, it is also possible to adopt a printing method in which a blanket cylinder is fixed (but vertically movable) and a substrate stage and a plate stage move, and a printing method in which a sleeve plate and a substrate stage are fixed and a blanket cylinder moves.

### Fourth Embodiment

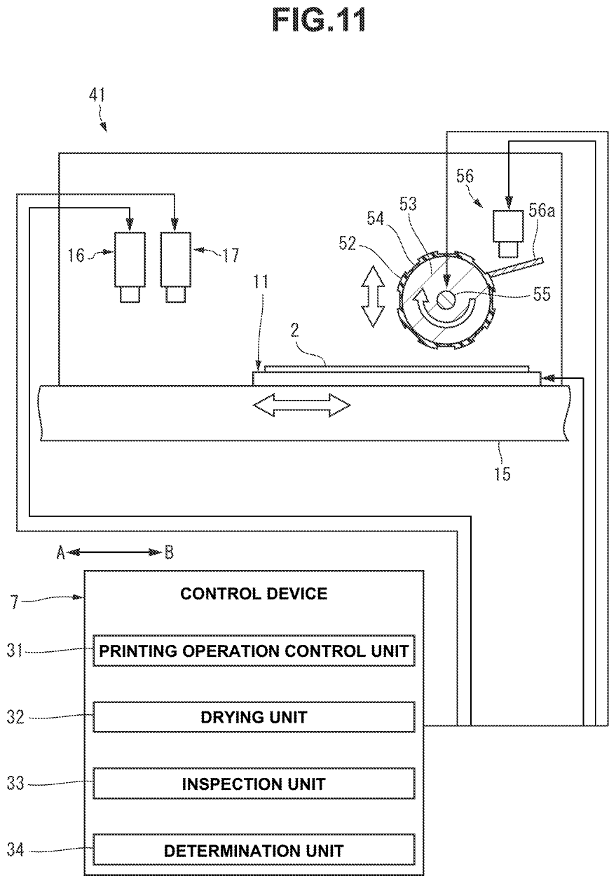

In each of the above-described first to third embodiments, an example in which the present invention is applied to the gravure offset printing device 1 or 41 in which the transfer member 14 performs the transfer operation is disclosed. However, the present invention is also applicable to a direct gravure printing device as shown in FIGS. 11 to 15. The same reference numerals as explained with reference to FIGS. 1 to 10 denote the same or equivalent members in FIGS. 11 to 15, and a detailed explanation thereof will suitably be omitted.

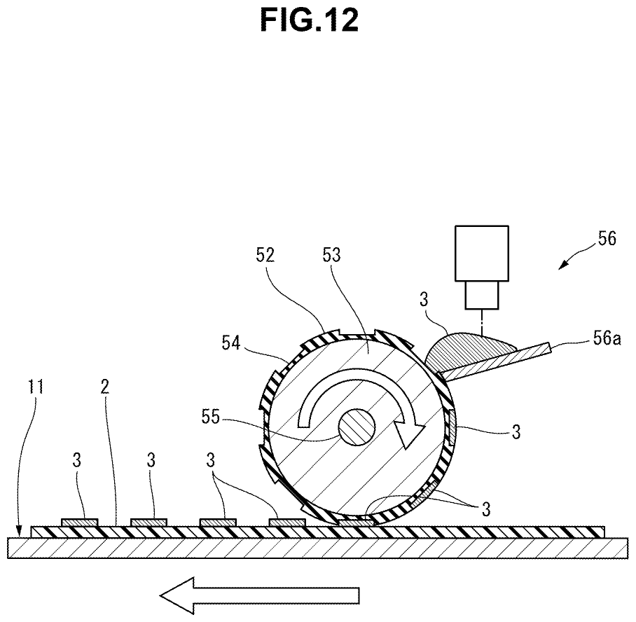

A direct gravure printing device 51 shown in FIG. 11 directly prints conductive paste 3 (see FIG. 12) on the substrate 2 by using a cylindrical intaglio plate 52.

The intaglio plate 52 is placed above a substrate stage 11 such that the intaglio plate 52 is attached to the outer circumferential surface of a plate cylinder 53 so as to rotate together with the plate cylinder 53. A plurality of recessed portions 54 (see FIG. 12) are formed on the outer circumferential surface of the intaglio plate 52 so as to form predetermined printing patterns. The intaglio plate 52 according to this embodiment is formed by a material that elastically deforms when pushed against a substrate 2 on the substrate stage 11. The plate cylinder 53 rotates around a horizontally extending spindle 55 and moves vertically. A control device 7 controls the operation of the plate cylinder 53.

A paste supply device 56 is placed near the plate cylinder 53. The paste supply device 56 according to this embodiment includes a blade 56a that is in contact with the outer circumferential surface of the intaglio plate 52, and supplies the conductive paste 3 on the blade 56a from above. When the intaglio plate 52 rotates in a state in which the conductive paste 3 supplied on the blade 56a is blocked by the intaglio plate 52, the conductive paste 3 is filled in recessed portions 54 of the intaglio plate 52, and excess conductive paste 3 is scraped off by the blade 56a. The control device 7 controls the operation of the paste supply device 56.

The substrate stage 11 holds the substrate 2 in a horizontal state, and moves on the base 15 in the horizontal direction (the left-and-right direction indicated by arrows A and B in FIG. 11) perpendicular to the axial direction of the plate cylinder 53. The control device 7 controls the operation of the substrate stage 11.

Like the control devices disclosed in the above-described first and second embodiments, the control device 7 includes a printing operation control unit 31, a drying unit 32, an inspection unit 33, and a determination unit 34, and controls the operation of each device so that the conductive paste 3 is printed on the substrate 2 by one of two types of printing methods to be described later. The two types of printing methods are a printing method that repeats a series of printing operations as in the above-described first embodiment, and a printing method that repeats a transfer operation in one position as in the second embodiment.

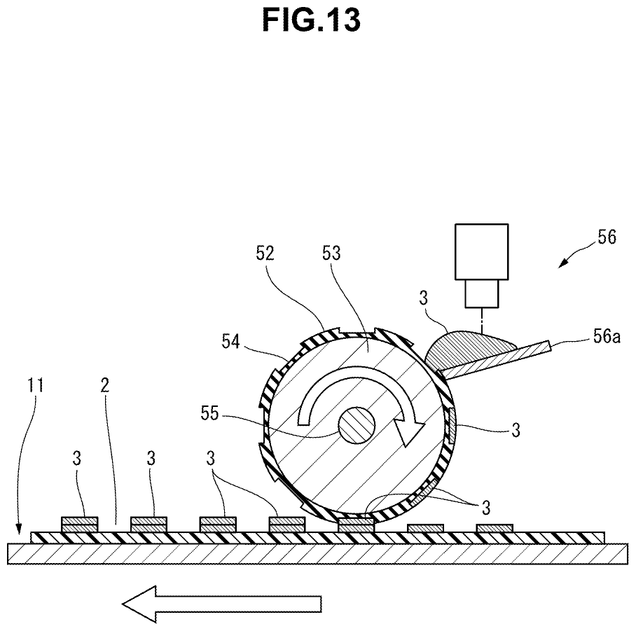

The printing method that repeats a series of printing operations is a method shown in the flowchart of FIG. 3. In this embodiment, as shown in FIGS. 12 and 13, conductive paste filling step S1, reception step S2, and transfer step S3 of the flowchart shown in FIG. 3 are performed by supplying the conductive paste 3 on the blade 56a by the paste supply device 24 while rotating the plate cylinder 53 in contact with the substrate 2. Note that although not shown, conductive paste filling step S1 and reception step S2 can be performed in a state in which the plate cylinder 53 is so raised as to separate the intaglio plate 52 upward from the substrate 2. As shown in FIG. 12, when the plate cylinder 53 rotates and the substrate stage 11 moves in parallel to the rotational direction of the plate cylinder 53 with the intaglio plate 52 being in contact with the substrate 2, the conductive paste 3 in the recessed portions 54 of the intaglio plate 52 is transferred to the substrate 2.

After the conductive paste 3 is transferred to all printing positions on the substrate 2, drying step S4, inspection step S5, and determination step S6 are performed. If NO in determination step S6, i.e., if the lamination height of the conductive paste 3 on the substrate 2 has not reached a target height, the substrate stage 11 returns to the initial position, and a series of printing operations from conductive paste filling step S1 to determination step S6 are repeated. When the series of printing operations are thus repeated, another layer of the conductive paste 3 is overlaid on the conductive paste 3 on the substrate 2, as shown in FIG. 13. Even when adopting this embodiment, therefore, a printing pattern laminate made of the conductive paste 3 laminated into the shape of the printing pattern on the substrate 2 is formed.

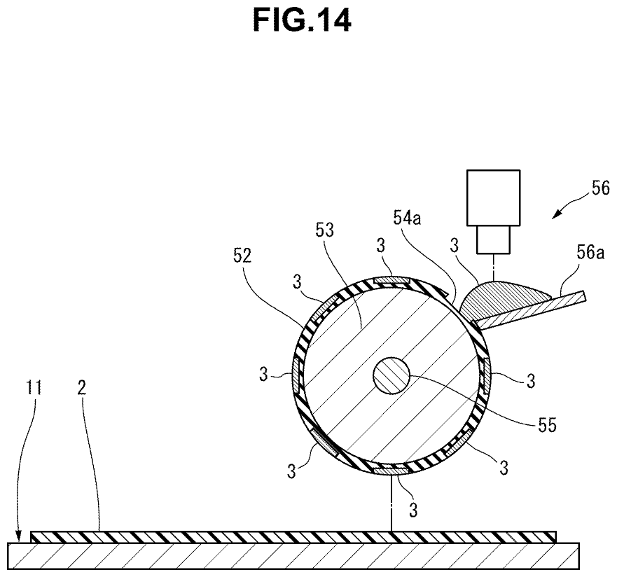

The printing method that repeats a transfer operation in one position is a method shown in a flowchart of FIG. 7. In this embodiment, as shown in FIG. 14, conductive paste filling step S1 and reception step S2 of the flowchart shown in FIG. 7 are performed by raising the plate cylinder 53 so as to separate the intaglio plate 52 upward from the substrate 2, and supplying the conductive paste 3 on the blade 56a by the paste supply device 56 while rotating the plate cylinder 53. When adopting this embodiment, the intaglio plate 52 has a plurality of recessed portions 54a having the same shape (the identical printing pattern). In this embodiment, the recessed portion 54a is a “printing pattern portion” in the invention described in claim 2.

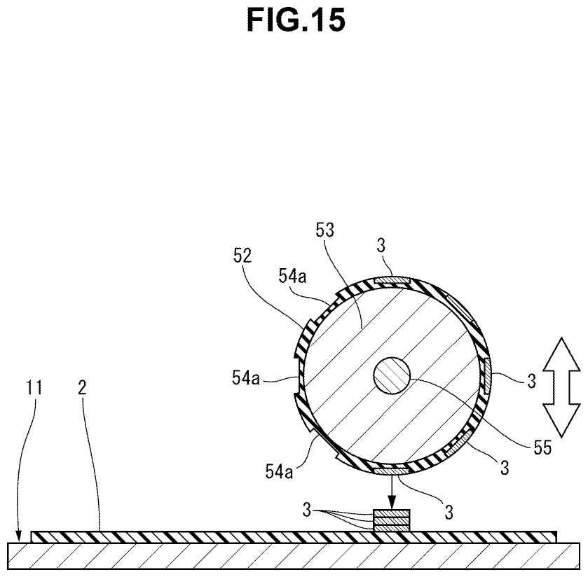

Transfer step S3 is performed after the conductive paste 3 is filled in all the recessed portions 54a of the plate cylinder 53. As shown in FIG. 15, transfer step S3 is performed by vertically reciprocating the plate cylinder 53 and rotating the plate cylinder 53 so as to shift the phase at a predetermined angle equivalent to the interval between the recessed portions 54a, such that the plate cylinder 53 moves down in a state in which the recessed portion 54a is in the lowermost position. After transfer step S3 is performed, drying step S4, inspection step S5, determination steps S6 and S7, and the like are performed. Consequently, as shown in FIG. 15, another layer of the conductive paste 3 is overlaid on the conductive paste 3 on the substrate 2.

Even when adopting this embodiment, therefore, a printing pattern laminate made of the conductive paste 3 laminated into the printing pattern shape is formed on the substrate 2. Note that in the fourth embodiment, an example in which the plate cylinder 53 moves vertically and the substrate stage 11 moves horizontally is disclosed. However, it is also possible to adopt an arrangement in which the plate cylinder 53 does not move either vertically or horizontally and the substrate stage 11 moves vertically and horizontally, an arrangement in which the plate cylinder 53 moves horizontally and the substrate stage 11 moves vertically, or an arrangement in which the plate cylinder 53 moves vertically and horizontally and the substrate stage 11 does not move either vertically or horizontally.

### Fifth Embodiment

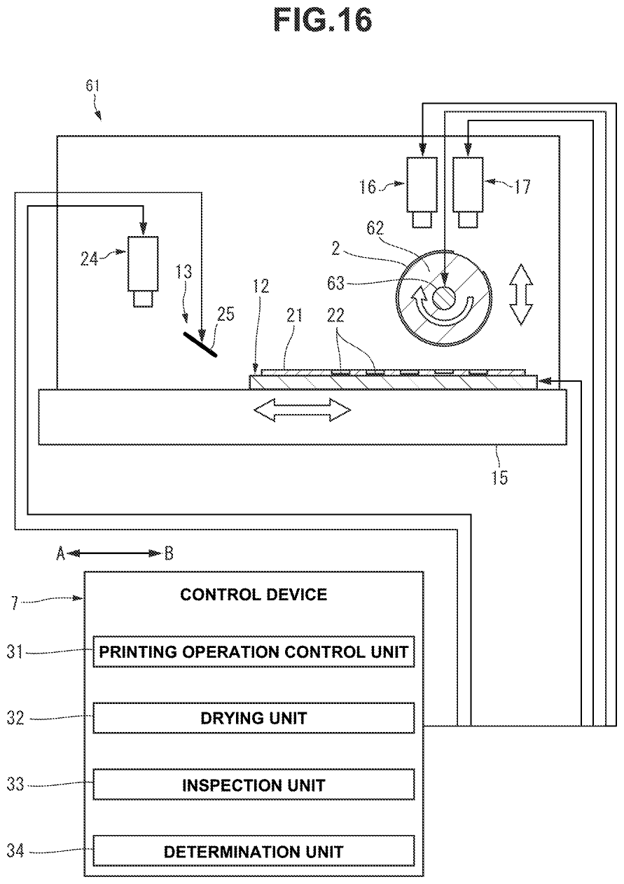

When applying the present invention to a direct gravure printing device, a configuration shown in FIGS. 16 to 18C can be adopted. The same reference numerals as explained with reference to FIGS. 1 to 10 denote the same or equivalent members in FIGS. 16 to 18C, and a detailed explanation thereof will appropriately be omitted.

A direct gravure printing device 61 shown in FIG. 16 directly prints conductive paste 3 (see FIG. 12) on a cylindrical substrate 2 by using a flat intaglio plate 21. The intaglio plate 21 is held on a plate stage 12 and moves horizontally with respect to a base 15 together with the plate stage 12. A plurality of recessed portions 22 are formed in the intaglio plate 21 so as to obtain predetermined printing patterns. When adopting this embodiment, the intaglio plate 21 is formed by using an elastically deformable material, or an elastic cushion material (not shown) is inserted between the intaglio plate 21 and the plate stage 12. This makes it possible to sufficiently push the substrate 2 against the intaglio plate 21.

The substrate 2 is formed into a sheet having a flat shape in a natural state and held as it is wound on the outer circumferential surface of a substrate support cylinder 62 having a columnar shape. In this embodiment, the substrate support cylinder 62 is equivalent to a “substrate stage” in the present invention. The substrate support cylinder 62 rotates around a horizontally extending spindle 63, and moves vertically. A control device 7 controls the operation of the substrate support cylinder 62.

Like the control device 7 disclosed in the above-described first and second embodiments, the control device 7 includes a printing operation control unit 31, a drying unit 32, an inspection unit 33, and a determination unit 34, and controls the operation of each device so as to print the conductive paste 3 on the substrate 2 by one of two types of printing methods to be described below. The two types of printing methods are a printing method that repeats a series of printing operations as in the above-described first embodiment, and a printing method that repeats a transfer operation in one position as in the second embodiment.

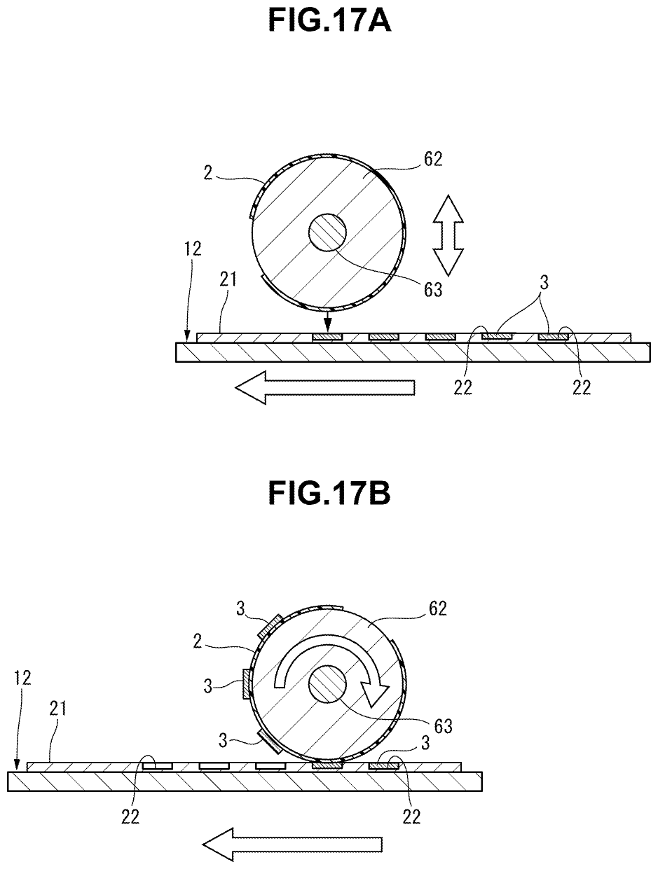

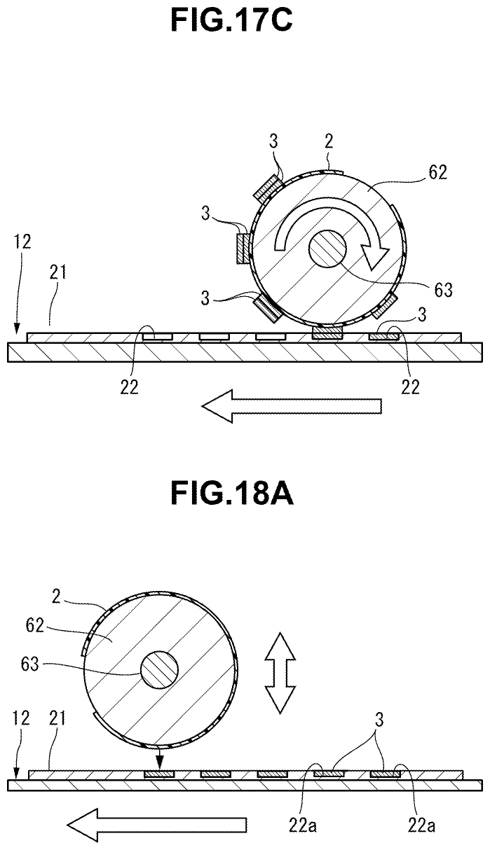

The printing method that repeats the series of printing operations is a method shown in the flowchart of FIG. 3. In this embodiment, conductive paste filling step S1 and reception step S2 of the flowchart shown in FIG. 3 are performed by supplying the conductive paste 3 to the intaglio plate 21 by a paste supply device 24 (see FIG. 16), in a state in which the substrate support cylinder 62 is separated upward from the intaglio plate 21 as shown in FIG. 17A. The conductive paste 3 supplied on the intaglio plate 21 is filled in the recessed portions 22 when the plate stage 12 moves in a state in which a blade 25 of a scraper 13 is in contact with the intaglio plate 21.

In this embodiment, as shown in FIGS. 17B and 17C, transfer step S3 is performed by pressing the substrate 2 against the intaglio plate 21 by moving down the substrate support cylinder 62, and rotating the substrate support cylinder 62 and moving the plate stage 12 in a direction along the rotational direction of the substrate support cylinder 62. When transfer step S3 is performed, the conductive paste 3 in the recessed portion 22 is transferred to the substrate 2. After transfer step S3 is performed, drying step S4, inspection step S5, and determination step S6 are performed.

If NO in determination step S6, i.e., if the lamination height of the conductive paste 3 on the substrate 2 has not reached a target height, the substrate support cylinder 62 rises and returns to the initial position, and the series of printing operations from conductive paste filling step S1 to determination step S6 are repeated. When the series of printing operations are thus repeated, another layer of the conductive paste 3 is overlaid on the conductive paste 3 on the substrate 2, as shown in FIG. 17C. Even when adopting this printing method, therefore, a printing pattern laminate made of the conductive paste 3 laminated into the printing pattern shape is formed on the substrate 2.

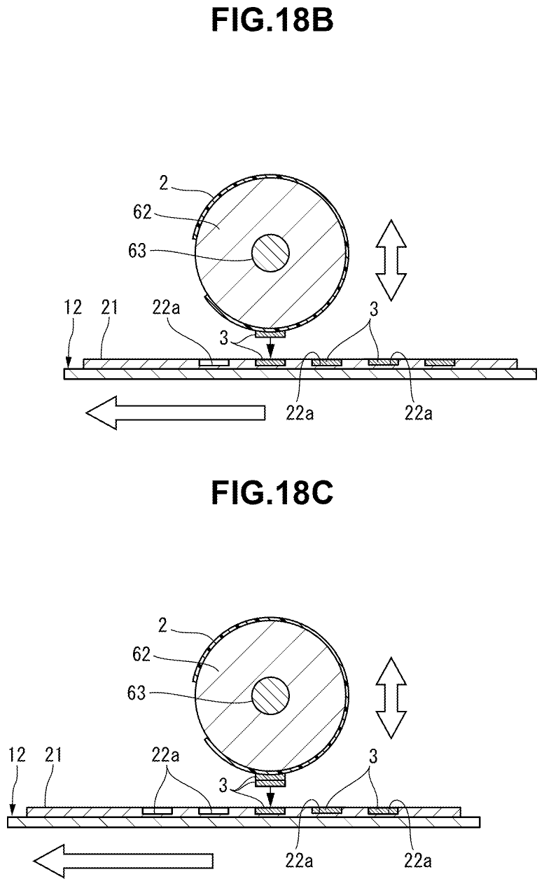

The printing method that repeats the transfer operation in one position is a method shown in the flowchart of FIG. 7. In this embodiment, as shown in FIG. 18A, conductive paste filling step S1 and reception step S2 in the flowchart shown in FIG. 7 are performed by supplying the conductive paste 3 to the intaglio plate 21 by the paste supply device 24 (see FIG. 16), in a state in which the substrate support cylinder 62 is separated upward from the intaglio plate 21. The conductive paste 3 supplied on the intaglio plate 21 is filled in recessed portions 22a as the plate stage 12 moves in a state in which the blade 25 of the scraper 13 is in contact with the intaglio plate 21. When adopting this embodiment, the intaglio plate 21 has a plurality of recessed portions 22a having the same shape (the identical printing pattern). In this embodiment, the recessed portion 22a is equivalent to a “printing pattern portion” in the invention described in claim 2.

Transfer step S3 is performed after the conductive paste 3 is filled in all the recessed portions 22a of the plate cylinder 53. As shown in FIG. 18B, transfer step S3 is performed by vertically reciprocating the substrate support cylinder 62 and intermittently moving the plate stage 12 by the formation pitch of the recessed portions 22a, so that the substrate 2 moves down in a state in which a predetermined printing position is in the lowermost position. After transfer step S3 is performed, drying step S4, inspection step S5, determination steps S6 and S7, and the like are performed, and another layer of the conductive paste 3 is overlaid on the conductive paste 3 on the substrate 2, as shown in FIG. 18C.

Even when adopting this embodiment, a printing pattern laminate made of the conductive paste 3 laminated into the printing pattern shape on the substrate 2 is formed. Note that in the fifth embodiment, an example in which the substrate support cylinder 62 moves vertically and the plate stage 12 moves horizontally is disclosed. However, it is also possible to adopt an arrangement in which the position of the substrate support cylinder 62 remains unchanged and the plate stage 12 moves vertically and horizontally, an arrangement in which the substrate support cylinder 62 moves horizontally and the plate stage 12 moves vertically, or an arrangement in which the substrate support cylinder 62 moves vertically and horizontally and the position of the plate stage 12 remains unchanged.

### EXPLANATION OF THE REFERENCE NUMERALS AND SIGNS

1, 41 . . . gravure offset printing device (gravure printing device), 2 . . . substrate, 3 . . . conductive paste, 4 . . . line (printing pattern laminate), 5 . . . bump (printing pattern laminate), 7 . . . control device, 11 . . . substrate stage, 12 . . . plate stage, 14 . . . transfer member, 16 . . . drying device, 17 . . . inspection device, 21, 52 . . . intaglio plate (plate), 22 . . . printing pattern portion, 22a, 54a . . . recessed portion (printing pattern portion), 51, 61 . . . direct gravure printing device (gravure printing device), 62 . . . substrate support cylinder (substrate stage)

1. A gravure printing device comprising:
a substrate stage configured to hold a substrate as an object of printing;
a plate configured to hold conductive paste in a predetermined printing pattern where the conductive paste is placed at a position corresponding to a position of an electrode on the substrate; and
a controller configured to control a series of printing operations including a supply operation of supplying the conductive paste to the printing pattern of the plate and a transfer operation of transferring the conductive paste to the substrate,
wherein the controller is configured to repeatedly perform the series of printing operations a plurality of times with respect to an identical printing position on the substrate, until a printing pattern laminate made of the conductive paste laminated into a shape of the printing pattern is formed on the electrode on the substrate.

2. A gravure printing device comprising:
a substrate stage configured to hold a substrate as an object of printing;
a plate including a plurality of printing pattern portions configured to hold conductive paste in predetermined printing patterns; and
a controller configured to control a series of printing operations including a supply operation of supplying the conductive paste to all the printing pattern portions of the plate and a transfer operation of transferring the conductive paste to the substrate,
wherein the controller is configured to cause the conductive paste for each printing pattern portion to be transferred to an printing position on the substrate, until a printing pattern laminate made of the conductive paste laminated into a shape of the printing pattern is formed on the substrate.

3. The gravure printing device according to claim 1, further comprising a transfer member configured to receive, from the plate, the conductive paste supplied to the plate and transfer the conductive paste to the substrate,
wherein the controller is configured to cause the transfer member to perform the transfer operation.

4. The gravure printing device according to claim 1, wherein the controller is configured to cause the plate to perform the transfer operation by transferring the conductive paste supplied to the plate, directly to the substrate from the plate.

5. A gravure printing device comprising:
a substrate stage configured to hold a substrate as an object of printing;
a plate configured to hold conductive paste in a predetermined printing pattern;
a transfer member configured to receive the conductive paste from the plate and transfer the conductive paste to the substrate; and
a controller configured to control a series of printing operations from a receiving operation in which the transfer member receives the conductive paste to a transfer operation of transferring the conductive paste to the substrate,
wherein the transfer member is configured to repeatedly receive the conductive paste a plurality of times from the plate to an identical receiving position in the receiving operation, and
the transfer member is configured to transfer the conductive paste laminated in the identical receiving position on the transfer member to the substrate in the transfer operation,
whereby a printing pattern laminate made of the conductive paste laminated into a shape of the printing pattern is formed on the substrate.

6. The gravure printing device according to claim 1, further comprising a dryer configured to dry the conductive paste transferred to the substrate,
wherein the controller is configured to control the dryer such that the dryer dries the conductive paste transferred as a lower layer to the substrate, before the conductive paste as an upper layer is printed on the conductive paste as the lower layer.

7. The gravure printing device according to claim 1, further comprising an indicator configured to measure a lamination state of the laminated conductive paste,
wherein the controller is configured to control the series of printing operations until the conductive paste is transferred to the substrate, based on a measurement result of the indicator.

8. The gravure printing device according to claim 7, wherein the controller is configured to perform a correcting operation of correcting the laminated conductive paste to a predetermined lamination state, based on the inspection result of the indicator.

9. The gravure printing device according to claim 2, further comprising a transfer member configured to receive, from the plate, the conductive paste supplied to the plate and transfer the conductive paste to the substrate,
wherein the controller is configured to cause the transfer member to perform the transfer operation.

10. The gravure printing device according to claim 2, wherein the controller is configured to cause the plate to perform the transfer operation by transferring the conductive paste supplied to the plate, directly to the substrate from the plate.

11. The gravure printing device according to claim 2, further comprising a dryer configured to dry the conductive paste transferred to the substrate,
wherein the controller is configured to control the dryer such that the dryer dries the conductive paste transferred as a lower layer to the substrate, before the conductive paste as an upper layer is printed on the conductive paste as the lower layer.

12. The gravure printing device according to claim 2, further comprising an indicator configured to measure a lamination state of the laminated conductive paste,
wherein the controller is configured to control the series of printing operations until the conductive paste is transferred to the substrate, based on a measurement result of the indicator.

13. The gravure printing device according to claim 12, wherein the controller is configured to perform a correcting operation of correcting the laminated conductive paste to a predetermined lamination state, based on the inspection result of the indicator.

14. The gravure printing device according to claim 5, further comprising an indicator configured to measure a lamination state of the laminated conductive paste,
wherein the controller is configured to control the series of printing operations until the conductive paste is transferred to the substrate, based on a measurement result of the indicator.

15. The gravure printing device according to claim 14, wherein the controller is configured to perform a correcting operation of correcting the laminated conductive paste to a predetermined lamination state, based on the inspection result of the indicator.
